(19) United States
(12) Patent Application Publication
(10) Pub. No.: US 2025/0028868 A1
(43) Pub. Date: Jan. 23, 2025

(54) Intelligent building scene drawing system

(71) Applicant: YU-SHENG HUANG, New Taipei City (TW)

(72) Inventor: YU-SHENG HUANG, New Taipei City (TW)

(21) Appl. No.: 18/777,862

(22) Filed: Jul. 19, 2024

(30) Foreign Application Priority Data
Jul. 20, 2023 (TW) 112127179

(51) Int. Cl. G06F 30/13

(52) U.S. Cl. CPC G06F 30/13

(57) ABSTRACT

An intelligent-building-scene-drawing system comprises an input-device for inputting operations by a user and a server with function of connecting to internet. The server has a user-interface including a map-module, an object-database, an intelligent-learning-drawing module and a processing-module. The map-module provides a real-time electronic-map of a location of an object information after inputting the object information. The object-database is built-in with a plurality of object models of various kinds of buildings or facilities. The intelligent-learning-drawing module is capable of selecting one of the object models from the object-database that matches a color, a shape or an appearance of a building or a facility of the electronic-map to generate a scene-graph which mimics the building or the facility of the electronic-map, and the building or the facility of the electronic-map is overlaid by the scene-graph. The electronic-map beyond the scene-graph is overlaid by blank by the processing-module.

### FIELD OF THE INVENTION

The present invention is related to an intelligent building scene drawing system, especially an intelligent building scene drawing system providing quick editing, modification and accurate positioning, which is especially suitable for use in large parks with multiple buildings such as schools and hospitals.

### BACKGROUND OF THE INVENTION

Conventional architectural plan drawings are produced through editing on third-party tools. Take large parks with multiple buildings, such as schools or hospitals, as an example, most of them use simple blocks to create a rough location. However, it lacks rendering efficiency, accuracy and real-time information. It will also be very troublesome if modifications such as additions, deletions, or changes are needed in the future. The uncertainty of assets makes management even more difficult.

Furthermore, asset management is the basis for ensuring school teaching work. How to strengthen school asset management is a difficult problem faced by many schools. Due to limitations of their own management systems, most schools focus more on teaching. Insufficient attention and not strict enough management to the assets occupied by the unit (especially fixed assets) will lead to low utilization and even assets loss.

Therefore, it has always been the research direction of the inventor of the present invention to provide a drawing system that can be quickly edited and provide clear, correct and consistent with the actual location and scene of the building or facility.

### SUMMARY OF THE INVENTION

The main object of the present invention is to provide an intelligent building scene drawing system that can be quickly edited, modified and accurately positioned.

In order to solve the above described problems and to achieve the expected effect, the present invention provides an intelligent building scene drawing system, which comprises an input device and a server with function of connecting to internet. The input device is used for inputting operations by a user. The server is connected to the input device. The server is provided with a user interface. The user interface at least includes a map module, an object database, an intelligent learning drawing module and a processing module. The map module provides a real-time electronic map of a location of an object information after the user inputs the object information. The electronic map includes at least one aerial photo of a building or a facility. The object database is built-in with a plurality of object models of various kinds of buildings or facilities. The intelligent learning drawing module is connected to the electronic map and the object database. The intelligent learning drawing module is capable of selecting one of the object models from the object database that matches a color, a shape or an appearance of the building or the facility of the electronic map, and then adjusting a scale of the one of the object models to generate a scene graph which mimics the building or the facility of the electronic map, and the building or the facility of the electronic map is overlaid by the scene graph. The processing module is connected to the map module. After the building or the facility of the electronic map is overlaid by the scene graph, the electronic map beyond the scene graph is overlaid by blank by the processing module.

In implementation, the intelligent learning drawing module is trained by an AI deep learning model.

In implementation, a drawing template is formed by adjusting a resolution, an orientation, a size or a scale of the electronic map, so that the scene graph mimicking the building or the facility of the electronic map is capable of being generated on the drawing template by the intelligent learning drawing module.

In implementation, the map module uses Google Map to provide the real-time electronic map of the location of the object information.

In implementation, the object models of buildings or facilities required by the user are capable of being generated through a large language model (LLM).

For further understanding the characteristics and effects of the present invention, some preferred embodiments referred to drawings are in detail described as follows.

### BRIEF DESCRIPTION OF DRAWINGS

FIG. 1 is an architecture diagram of an embodiment of an intelligent building scene drawing system of the present invention.

FIG. 2 is an architecture diagram of an embodiment of a user interface of the present invention.

### DETAILED DESCRIPTIONS OF PREFERRED EMBODIMENTS

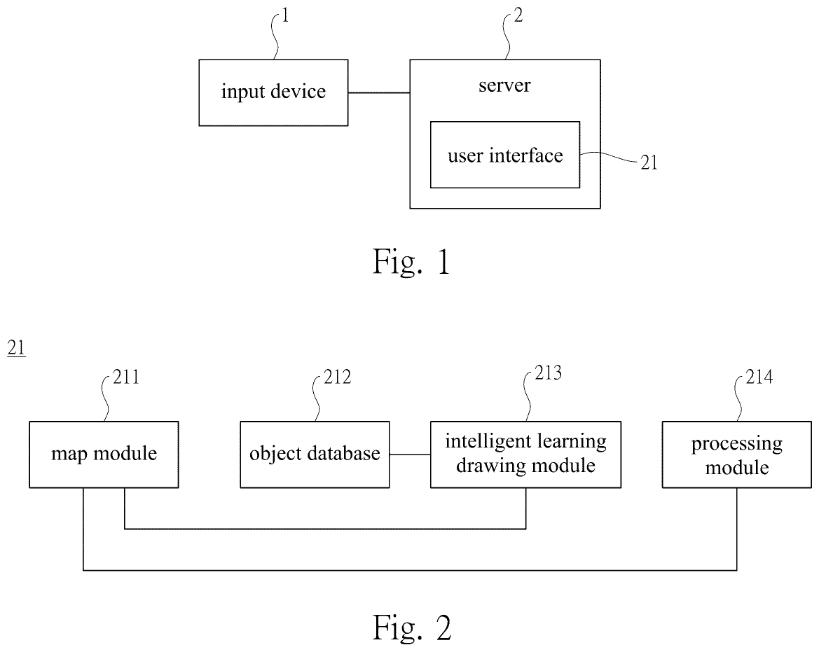

Please refer to FIGS. 1 and 2, which show a preferred embodiment of an intelligent building scene drawing system of the present invention. The intelligent building scene drawing system of the present invention comprises an input device 1 and a server 2 with function of connecting to internet. The input device 1 is used for inputting operations by a user. The server 2 is connected to the input device 1. The server 2 is provided with a user interface 21.

The user interface 21 at least includes a map module 211, an object database 212, an intelligent learning drawing module 213 and a processing module 214. The map module 211 provides a real-time electronic map of a location of an object information after the user inputs the object information, and the electronic map includes at least one aerial photo of a building or a facility. The map module 211 uses Google Map to provide the real-time electronic map of the location of the object information. The object database 212 is built-in with a plurality of object models of various kinds of buildings or facilities. The intelligent learning drawing module 213 is connected to the electronic map and the object database 212. After the intelligent learning drawing module 213 is trained by an AI deep learning model, the intelligent learning drawing module 213 is capable of selecting one of the object models from the object database 212 that matches a color, a shape or an appearance of the building or the facility of the electronic map, and then adjusting a scale of the one of the object models to generate a scene graph which mimics the building or the facility of the electronic map, and the building or the facility of the electronic map is overlaid by the scene graph. The processing module 214 is connected to the map module 211. After the building or the facility of the electronic map is overlaid by the scene graph, the electronic map beyond the scene graph is overlaid by blank by the processing module 214.

In implementation, taking an example of generating a scene graph of a school, when the user inputs operations through the input device 1, after connecting to the user interface 21 of the server 2, the user can input the coordinates, address or name of the school into the map module 211 of the user interface 21. An electronic map of a location of the school can be instantly located, since the map module 211 uses Google Map to provide the electronic map. And after adjusting a resolution, a transparency, an orientation, a size or a scale of the electronic map, the intelligent learning drawing module 213 after trained by an AI deep learning model is capable of selecting one of the object models from the object database 212 that matches a color, a shape or an appearance of the building or the facility of the electronic map, and then adjusting a scale of the one of the object models to generate a scene graph which mimics the building or the facility of the electronic map, and the building or the facility of the electronic map is overlaid by the scene graph. For example, generating an object model to overlay the object model on a square green building in the school on the electronic map, wherein the object model is also a square green building; or generating object models to overlay the object models on the facilities of a playground, a basketball court or even slides in the school on the electronic map, wherein the object models are also a playground, a basketball court or even slides with the same shape, same size or same color.

Through the above method, after generating various corresponding object models to overlay the object models on all buildings of the school on the electronic map, wherein the object models are corresponding to the all buildings of the school, and the electronic map beyond the object models is overlaid by blank by the processing module 21, and a complete scene graph of the school is then generated.

Moreover, a drawing template is formed by adjusting a resolution, an orientation, a size or a scale of the electronic map, so that the scene graph mimicking the building or the facility of the electronic map is capable of being generated on the drawing template by the intelligent learning drawing module 213. The object models of buildings or facilities required by the user are capable of being generated through a large language model (LLM).

The present invention has the following advantages:
1. Through the design of the map module and the intelligent learning drawing module, the present invention allows drawing directly on the building of the electronic map, so that the location of the building of the completed scene graph is consistent with the actual scene. And anyone can understand it more clearly when watching it. Even if the actual building is demolished or an actual building is added in the future, it can be completed accurately and quickly through the drawing system of the present invention.
2. Through the design of the intelligent learning drawing module of the present invention, the user can quickly complete all object models in the scene graph, without the need for time-consuming drawing manually or spending time on searching for matches in the object database. In the meantime, the object models of buildings or facilities required by the user are also capable of being generated through a large language model (LLM), which can be adjusted and modified at any time.

As disclosed in the above description and attached drawings, the present invention can provide an intelligent building scene drawing system. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

What is claimed is:

1. An intelligent building scene drawing system comprising:
an input device for inputting operations by a user; and
a server with function of connecting to internet, the server is connected to the input device, the server is provided with a user interface, wherein the user interface includes:
a map module, the map module provides a real-time electronic map of a location of an object information after the user inputs the object information, and the electronic map includes at least one aerial photo of a building or a facility;
an object database built-in with a plurality of object models of various kinds of buildings or facilities;
an intelligent learning drawing module connected to the electronic map and the object database, the intelligent learning drawing module is capable of selecting one of the object models from the object database that matches a color, a shape or an appearance of the building or the facility of the electronic map, and then adjusting a scale of the one of the object models to generate a scene graph which mimics the building or the facility of the electronic map, and the building or the facility of the electronic map is overlaid by the scene graph; and
a processing module connected to the map module, after the building or the facility of the electronic map is overlaid by the scene graph, the electronic map beyond the scene graph is overlaid by blank by the processing module.

2. The intelligent building scene drawing system according to claim 1, wherein the intelligent learning drawing module is trained by an AI deep learning model.

3. The intelligent building scene drawing system according to claim 1, wherein a drawing template is formed by adjusting a resolution, an orientation, a size or a scale of the electronic map, so that the scene graph mimicking the building or the facility of the electronic map is capable of being generated on the drawing template by the intelligent learning drawing module.

4. The intelligent building scene drawing system according to claim 1, wherein the map module uses Google Map to provide the real-time electronic map of the location of the object information.

5. The intelligent building scene drawing system according to claim 1, wherein the object models of buildings or facilities required by the user are capable of being generated through a large language model (LLM).
